(19) United States
(12) Patent Application Publication
(10) Pub. No.: US 2018/0057935 A1
(43) Pub. Date: Mar. 1, 2018

(54) ENDPOINT DETECTION FOR A CHAMBER CLEANING PROCESS

(71) Applicant: Applied Materials, Inc., Santa Clara, CA (US)

(72) Inventors: Edward BUDIARTO, Fremont, CA (US); Beom Soo PARK, San Jose, CA (US); Soo Young CHOI, Fremont, CA (US); Fei PENG, San Jose, CA (US); Todd EGAN, Fremont, CA (US)

(21) Appl. No.: 15/684,677

(22) Filed: Aug. 23, 2017

Related U.S. Application Data
(60) Provisional application No. 62/378,487, filed on Aug. 23, 2016.

(51) Int. Cl. C23C 16/44; B08B 9/08; B08B 7/00; B08B 9/46; G01N 21/94; H01J 37/32

(52) U.S. Cl. CPC C23C 16/4405; B08B 9/0865; H01J 37/32853; B08B 9/46; G01N 21/94; B08B 7/0035

(57) ABSTRACT

Embodiments of the present invention provide an apparatus and methods for detecting an endpoint for a cleaning process. In one example, a method of determining a cleaning endpoint includes performing a cleaning process in a plasma processing chamber, directing an optical signal to a surface of a shadow frame during the cleaning process, collecting a return reflected optical signal reflected from the surface of the shadow frame, determining a change of reflectance intensity of the return reflected optical signal as collected, and determining an endpoint of the cleaning process based on the change of the reflected intensity. In another example, an apparatus for performing a plasma process and a cleaning process after the plasma process includes an optical monitoring system coupled to a processing chamber, the optical monitoring system configured to direct an optical beam light to a surface of a shadow frame disposed in the processing chamber.

### CROSS-REFERENCE TO RELATED APPLICATIONS

This application claims benefit of U.S. Provisional Application Ser. No. 62/378,487, filed Aug. 23, 2016 (Attorney Docket No. APPM/24275USL), of which is incorporated by reference in its entirety.

### BACKGROUND

### Field

Embodiments of the present invention generally relate to methods of detecting an endpoint for a cleaning process, and more particularly to, methods of detecting an endpoint for a cleaning process using an endpoint detection system to detect a change of reflectance during the cleaning process.

### Description of the Related Art

Display devices have been widely used for a wide range of electronic applications, such as TV, monitors, mobile phone, MP3 players, e-book readers, and personal digital assistants (PDAs) and the like. The display device is generally designed for producing desired image by applying an electric field to a liquid crystal that fills a gap between two substrates (e.g., a pixel electrode and a common electrode) and has anisotropic dielectric constant that controls the intensity of the dielectric field. By adjusting the amount of light transmitted through the substrates, the light and image intensity, quality and power consumption may be efficiently controlled.

A variety of different display devices, such as active matrix liquid crystal display (AMLCD) or an active matrix organic light emitting diodes (AMOLED), may be employed as light sources for display. In the manufacturing of display devices, an electronic device with high electron mobility, low leakage current and high breakdown voltage, would allow more pixel area for light transmission and integration of circuitry, thereby resulting in a brighter display, higher overall electrical efficiency, faster response time and higher resolution displays. Low film qualities of the material layers, such as dielectric layer with impurities or low film densities, formed in the device often result in poor device electrical performance and short service life of the devices. Thus, a stable and reliable method for forming and integrating film layers within TFT and OLED devices becomes crucial to provide a device structure with low film leakage, and high breakdown voltage, for use in manufacturing electronic devices with lower threshold voltage shift and improved the overall performance of the electronic device are desired.

A typical processing chamber for forming dielectric films for display devices includes a chamber body defining a process zone, a gas distribution assembly adapted to supply a gas from a gas supply into the process zone, a gas energizer, e.g., a plasma generator, utilized to energize the process gas to process a substrate positioned on a substrate support assembly, and a gas exhaust. During plasma processing, the energized gas is often comprised of ions, radicals and highly reactive species which are then deposited on the substrate as dielectric films. However, processing by-products are also often deposited on exposed chamber components which must be periodically cleaned typically with highly reactive fluorine.

Accordingly, in order to maintain cleanliness of the processing chamber, a periodic cleaning process is performed to remove the by-products from the processing chamber, typically with highly reactive chemicals. One commonly used technique to indicate the end of the cleaning process is based on monitoring the pressure inside the chamber, and terminating the cleaning process when specific pressure level or when a rate-of-change has been reached. Even with this pressure-based end-pointing scheme, the cleaning process is usually extended beyond the end-point marker to ensure that all film by-products are completely removed. The cleaning process is not uniform in distribution across the interior region of the processing chamber. The processing chamber corners are usually slowest to be cleaned, and any remaining films can flake off and fall onto the next substrate being processed, creating particle defects. However, over attack from the reactive species during the over-cleaning process reduces the lifespan of the chamber components and increases chamber maintenance frequency. Additionally, the chemicals used in the cleaning process are expensive consumables, such that unnecessarily long cleaning time becomes costly.

Other conventional end-point detection methods, such as plasma impedance monitoring, infrared absorption of by-products in exhaust line, and Residual Gas Analysis (RGA) monitoring, are all based on global signal monitoring, and therefore are not sufficiently sensitive to detect remaining films in local areas, such as chamber corners.

Therefore, there is a need for an improved process for cleaning endpoint control for maintaining cleanliness of the processing chamber as well as the integrity of the chamber components to increase the lifetime of chamber components and to reduce the cost of consumables.

### SUMMARY

Embodiments of the present invention provide an apparatus and methods for detecting an endpoint for a cleaning process. In one example, a method of determining a cleaning endpoint includes performing a cleaning process in a plasma processing chamber, directing an optical signal to a surface of a shadow frame during the cleaning process, collecting a return reflected optical signal reflected from the surface of the shadow frame, determining a change of reflectance intensity of the return reflected optical signal as collected, and determining an endpoint of the cleaning process based on the change of the reflected intensity.

In another example, an apparatus for performing a plasma process and a cleaning process after the plasma process includes an optical monitoring system coupled to a processing chamber, the optical monitoring system configured to direct an optical beam light to a surface of a shadow frame disposed in the processing chamber.

In yet another example, a method of determining a cleaning endpoint includes directing an optical signal to a surface of a shadow frame disposed in a processing chamber during a cleaning process, collecting a return reflected optical signal reflected from the surface of the shadow frame, and analyzing the return reflected optical signal to determine a film layer loss on the surface of the shadow frame.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depicts an apparatus utilized to perform a cleaning process after forming a dielectric layer on a substrate in accordance with one embodiment of the present invention;

FIGS. 2A-2C depict different examples of shadow frames utilized in the apparatus of FIG. 1 for endpoint detection;

FIG. 3 depicts a flow diagram of a method for detecting an endpoint in a cleaning process performed in the apparatus of FIG. 1; and

FIGS. 4A-4C depict spectrum indicating a film thickness variation on a shadow frame disposed in the apparatus of FIG. 1 during a cleaning process; and

FIGS. 5A-5B depicts another example of configurations of chamber components for cleaning endpoint detection.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for detecting an endpoint for a cleaning process performed in a processing chamber. In one example, an endpoint detection system is incorporated in a processing chamber to detect an endpoint for a cleaning process performed in the processing chamber. The endpoint of the cleaning process may be obtained when a change of reflectance intensity of an optical signal reflected from a surface of a shadow frame disposed in the processing chamber is detected. Although the discussions and illustrative examples focus on the cleaning endpoint detection during a cleaning process for cleaning dielectric by-products in the processing chamber, various embodiments of the invention can also be adapted for process monitoring of other suitable substrates, including transparent or dielectric substrates, or optical disks.

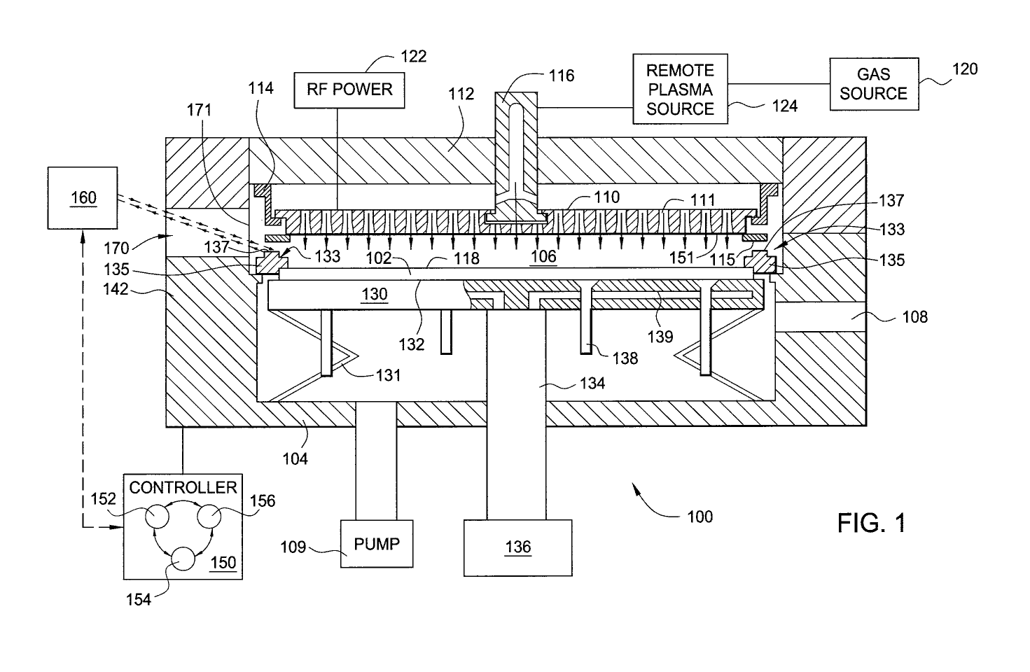

FIG. 1 is a schematic cross-section view of one embodiment of a chemical vapor deposition processing chamber 100 in which a dielectric layer, such as an insulating layer, may be deposited. One suitable chemical vapor deposition chamber, such as plasma enhanced CVD (PECVD), is available from Applied Materials, Inc., located in Santa Clara, Calif. It is contemplated that other deposition chambers, including those from other manufacturers, may be utilized to practice the present disclosure.

The chamber 100 generally includes walls 142, a bottom 104 and a lid 112 which bound a process volume 106. A gas distribution plate 110 and substrate support assembly 130 are disposed with in a process volume 106. The process volume 106 is accessed through a valve 108 formed through the wall 142 such that a substrate 102 may be transferred in to and out of the chamber 100.

The substrate support assembly 130 includes a substrate receiving surface 132 for supporting the substrate 102 thereon. A stem 134 couples the substrate support assembly 130 to a lift system 136 which raises and lowers the substrate support assembly 130 between substrate transfer and processing positions. Lift pins 138 are moveably disposed through the substrate support assembly 130 and are adapted to space the substrate 102 from the substrate receiving surface 132. The substrate support assembly 130 may also include heating and/or cooling elements 139 utilized to maintain the substrate support assembly 130 at a desired temperature. The substrate support assembly 130 may also include grounding straps 131 to provide an RF return path around the periphery of the substrate support assembly 130. A shadow frame 133 is placed over periphery of the substrate 102 when processing to prevent deposition on the edge of the substrate 102. Examples of the materials for the shadow frame include a metal material or ceramic materials, such as bare aluminum, aluminum oxide, aluminum nitride, aluminum oxynitride, alumina coating, an aluminum body with anodized coating/surface, stainless steel or alloys thereof.

The wall 142 of the processing chamber 100 may have an opening 170 opened to include a window 171 disposed therein that facilitates optical process monitoring from an optical monitoring system 160 disposed in the processing chamber 100. In one embodiment, the window 171 is comprised of quartz or other suitable material that is transmissive to a signal utilized by the optical monitoring system 160 mounted outside the processing chamber 100.

In one example, the optical monitoring system 160 is positioned to view at least one chamber component disposed in the process volume 106 of processing chamber 100 and/or a surface 137 of the shadow fame 133 disposed therein through the window 171. In one embodiment, the optical monitoring system 160 is mounted outside the processing chamber 100 and facilitates an integrated deposition process and a cleaning process performed after the deposition process that uses optical metrology to provide information that enables cleaning process adjustment to compensate for incoming substrate film thickness inconsistencies and to provide process state monitoring (such as cleaning rate, and the like) as needed. One optical monitoring system that may be adapted to benefit from the disclosure is a reflectometer metrology module.

In one embodiment, the optical monitoring system 160 may be utilized to detect an endpoint for a cleaning process performed after a deposition process. The optical monitoring system 160 is configured to detect optical signals through the window 171 reflected from the surface 137 of the shadow frame 133 or reflected from other portions of the chamber components disposed in the processing chamber 100. The surface 137 as discussed here may be any outer surface of the shadow frame 133 disposed in the processing chamber 100. It is noted that more than one window may be formed in the wall 142 or other locations of the processing chamber 100 which allows optical monitoring of various locations on the shadow frame 133 from its surface during the cleaning process. Alternatively, different numbers of windows may be provided at other locations of the wall 142, the lid 112, chamber body and/or the substrate support assembly 130 as needed.

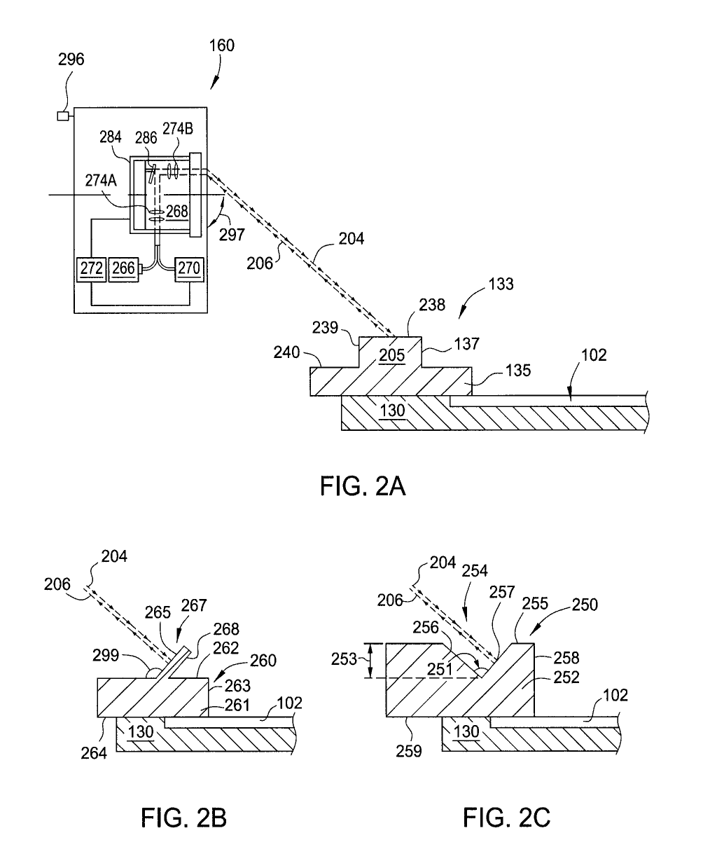

The optical monitoring system 160 comprises optical setup for operating in at least one of reflection, interferometry or transmission modes, and is configured for different types of measurements, such as reflectance or transmittance, interferometry, or optical emission spectroscopy, so as to determine an endpoint for a cleaning process. In one particular example, the optical monitoring system 160 is configured to direct a reflected light reflected back to the optical monitoring system 160. Depending on the application of interest, e.g., the material layers or substrate structure being processed, cleaning process endpoints may be detected based on a change in the reflectance or transmittance intensities, the number of interference fringes, or changes in optical emission intensities at specific wavelengths, or combination thereof. In one particular embodiment, the optical monitoring system 160 is configured to detect a cleaning endpoint based on a change in the reflectance reflected from the surface 137 of the shadow frame 133. The reflection mode of operation allows reflectance (or reflectometry) and interferometric measurement to be performed. Details configurations of the optical monitoring system 160 will be further discussed below with referenced to FIG. 2A.

The gas distribution plate 110 is coupled at its periphery to a lid 112 or wall 142 of the chamber 100 by a suspension 114, 115. The gas distribution plate 110 may also be coupled to the lid 112 by one or more center supports 116 to help prevent sag and/or control the straightness/curvature of the gas distribution plate 110. The gas distribution plate 110 may have different configurations with different dimensions. In an exemplary embodiment, the gas distribution plate 110 has a quadrilateral plan shape. The gas distribution plate 110 has a downstream surface 151 having a plurality of apertures 111 formed therein facing an upper surface 118 of the substrate 102 disposed on the substrate support assembly 130. The apertures 111 may have different shapes, number, densities, dimensions, and distributions across the gas distribution plate 110. In one embodiment, a diameter of the apertures 111 may be selected between about 0.01 inch and about 1 inch.

A gas source 120 is coupled to the lid 112 to provide gas through the lid 112 and then through the apertures 111 formed in the gas distribution plate 110 to the process volume 106. A vacuum pump 109 is coupled to the chamber 100 to maintain the gas in the process volume 106 at a desired pressure.

An RF power source 122 is coupled to the lid 112 and/or to the gas distribution plate 110 to provide a RF power that creates an electric field between the gas distribution plate 110 and the substrate support assembly 130 so that a plasma may be generated from the gases present between the gas distribution plate 110 and the substrate support assembly 130. The RF power may be applied at various RF frequencies. For example, RF power may be applied at a frequency between about 0.3 MHz and about 200 MHz. In one embodiment the RF power is provided at a frequency of 13.56 MHz.

In one embodiment, the edges of the downstream surface 151 of the gas distribution plate 110 may be curved so that a spacing gradient is defined between the edge and corners of the gas distribution plate 110 and substrate receiving surface 132 and, consequently, between the gas distribution plate 110 and the upper surface 118 of the substrate 102. The shape of the downstream surface 151 may be selected to meet specific process requirements. For example, the shape of the downstream surface 151 may be convex, planar, concave or other suitable shape. Therefore, the edge to corner spacing gradient may be utilized to tune the film property uniformity across the edge of the substrate, thereby correcting property non-uniformity in films disposed in the corner of the substrate. Additionally, the edge to center spacing may also be controlled so that the film property distribution uniformity may be controlled between the edge and center of the substrate. In one embodiment, a concave curved edge of the gas distribution plate 110 may be used so the center portion of the edge of the gas distribution plate 110 is spaced farther from the upper surface 118 of the substrate 102 than the corners of the gas distribution plate 110. In another embodiment, a convex curved edge of the gas distribution plate 110 may be used so that the corners of the gas distribution plate 110 are spaced farther than the edges of the gas distribution plate 110 from the upper surface 118 of the substrate 102.

A remote plasma source (RPS) 124, such as an inductively coupled remote plasma source, may also be coupled between the gas source and the gas distribution plate 110. Between processing substrates, a cleaning gas may be energized in the RPS 124 to remotely provide plasma utilized to clean chamber components. The cleaning gas entering the process volume 106 may be further excited by the RF power provided to the gas distribution plate 110 by the RF power source 122. Suitable cleaning gases include, but are not limited to, NF₃, F₂, and SF₆.

In one embodiment, the substrate 102 that may be processed in the chamber 100 may have a surface area of 10,000 cm² or more, such as 25,000 cm² or more, for example about 55,000 cm² or more. It is understood that after processing the substrate may be cut to form smaller other devices.

In one embodiment, the heating and/or cooling elements 139 may be set to provide a substrate support assembly temperature during deposition of about 600 degrees Celsius or less, for example between about 100 degrees Celsius and about 500 degrees Celsius, or between about 200 degrees Celsius and about 500 degrees Celsius, such as about 300 degrees Celsius and 500 degrees Celsius.

The nominal spacing during deposition between the upper surface 118 of the substrate 102 disposed on the substrate receiving surface 132 and the gas distribution plate 110 may generally vary between 400 mils and about 1,200 mils, such as between 400 mils and about 800 mils, or other distance required to obtain desired deposition results. In one exemplary embodiment wherein the gas distribution plate 110 has a concave downstream surface, the spacing between the center portion of the edge of the gas distribution plate 110 and the substrate receiving surface 132 is between about 400 mils and about 1400 mils, and the spacing between the corners of the gas distribution plate 110 and the substrate receiving surface 132 is between about 300 mils and about 1200 mils.

A controller 150 is coupled to the processing chamber 100 to control operation of the processing chamber 100. The controller 150 includes a central processing unit (CPU) 152, a memory 154, and a support circuit 156 utilized to control the process sequence and regulate the gas flows from the gas source 120 as well as the optical signal from the optical monitoring system 160. The CPU 152 may be any form of general purpose computer processor that may be used in an industrial setting. The software routines can be stored in the memory 154, such as random access memory, read only memory, floppy, or hard disk drive, or other form of digital storage. The support circuit 156 is conventionally coupled to the CPU 152 and may include cache, clock circuits, input/output systems, power supplies, and the like. Bi-directional communications between the controller 150 and the various components of the processing chamber 100 are handled through numerous signal cables.

FIG. 2A depicts one example of the optical monitoring system 160 that may emit a beam light (e.g., an optical signal) to the surface 137 of the shadow frame 133. In one example, the optical monitoring system 160 is positioned to view the surface 137 of the shadow frame 133. The surface 137 of the shadow frame 133 may include an upper surface 238, 240 or a sidewall surface 239 of the shadow frame 133.

The optical monitoring system 160 generally comprises a light source 266, a focusing assembly 268 for focusing an incident optical beam 204 from the light source 266 onto a discreet area (spot), such as the surface 137 of the shadow frame 133 disposed on the substrate support assembly 130, and a photodetector 270 for measuring the intensity of a reflected optical signal 206 reflected off the surface 137 of the shadow frame 133. An adjustment mechanism 296 may be provided to set an angle 297 of the incident optical beam 204 so that the surface 137 of the shadow frame 133 may be selectively positioned on a desired location on the shadow frame 133. The adjustment mechanism 296 may be an actuator, set screw or other device suitable for setting the angle 297 of incidence by moving (tilting) the optical monitoring system 160 itself or a component therein, such as with an optical beam positioner 284. The photodetector 270 may be a single wavelength or multi-wavelength detector, or a spectrometer. Based on the measured signal of the reflected optical signal 206, a computer system 272 calculates portions of the real-time waveform and compares it with a stored characteristic waveform pattern to extract information relating to the cleaning process. In one embodiment, the calculation may be based on slope changes or other characteristic changes in the detected signals, either in reflection or transmission mode, for example, when a film is cleaned to a target depth or thickness. Alternatively, the calculation may be based on interferometric signals as the depth of a trench or the thickness of a film changes during the cleaning process. In other examples, more detailed calculations may be performed based on reflected light signals obtained over a wide spectrum in order to determine the depth, width or thickness at any point during the cleaning process to determine cleaning rate/removal rate of the object being cleaned or removed.

The light source 266 may be monochromatic, polychromatic, white light, or other suitable light source. In general, the optical signal from the reflected optical signal 206 may be analyzed to extract information regarding the presence or absence of a layer (e.g., a dielectric or a conductive layer), or the thickness of certain material layers within the surface 137 of the shadow frame. The intensity of the incident optical beam 204 is selected to be sufficiently high intensity to provide the reflected optical signal 206 with a measurable intensity. The light source 266 can also be switched on and off to subtract background light. In one embodiment, the light source 266 provides polychromatic light, e.g., from an Hg—Cd lamp, an arc lamp, or a light emitting diode (LED) or LED array, which generates light in wavelength ranges from about 170 nm to about 800 nm, or about 200 to 800 nm, for example about 250 nm to about 800 nm. The light source 266 can be filtered to provide the incident optical beam 204 having selected frequencies. Color filters can be placed in front of the photodetector 270 to filter out all wavelengths except for a desired wavelength of light, prior to measuring the intensity of the reflected optical signal 206 entering the photodetector 270. The light can be analyzed by a spectrometer (array detector with a wavelength-dispersive element) to provide data over a wide wavelength range, such as ultraviolet to visible, from about 200 nm to 800 nm. The light source 266 can also comprise a flash lamp, e.g., a Xe or other halogen lamp, or a monochromatic light source that provides optical emission at a selected wavelength, for example, a He—Ne or ND-YAG laser. The light source 266 may be configured to operate in a continuous or pulsed mode. Alternatively, the wavelength range may be expanded into the deep UV as low as 170 nm or beyond using optical materials with stable deep UV transmission and purging air paths with inert gas or other suitable carrier gas, such as nitrogen gas.

One or more convex focusing lenses or concave mirrors 274A, 274B may be used to focus the incident optical beam 204 to the surface 137 of the shadow frame 133, and to focus the reflected optical signal 206 back on the active surface of photodetector 270. The area of the reflected optical signal 206 should be sufficiently large to activate a large portion of the active light-detecting surface of the photodetector 270. The incident and reflected optical beam and signals 204, 206 are directed through the transparent window 171 in the processing chamber 100 (depicted in FIG. 1) that allows the optical beams to pass in and out of the processing environment.

The diameter/size of the surface 137 being detected is generally about 2 mm to about 10 mm. The size of the surface 137 being detected (e.g., beam spot) can be altered based on different configurations of the shadow frame 133 being detected. Optionally, the optical beam positioner 284 may be used to move the incident optical beam 204 across the shadow frame 133 to a suitable portion of the shadow frame 133 to monitor the cleaning process. The optical beam positioner 284 may include one or more primary mirrors 286 that rotate at small angles to deflect the optical beam from the light source 266 onto different positions of the shadow frame 133. Additional secondary mirrors may be used (not shown) to direct the reflected optical signal 206 on the photodetector 270. The optical beam positioner 284 may also be used to scan the optical beam in a raster pattern across the surface of the shadow frame 133. In this embodiment, the optical beam positioner 284 comprises a scanning assembly consisting of a movable stage (not shown), upon which the light source 266, the focusing assembly 268 and the photodetector 270 are mounted. The movable stage can be moved through set intervals by a drive mechanism, such as a stepper motor or galvanometer, to scan the surface across the shadow frame 133.

The photodetector 270 comprises a light-sensitive electronic component, such as a photovoltaic cell, photodiode, phototransistor, or photomultiplier, which provides a signal in response to a measured intensity of the reflected optical signal 206. The signal can be in the form of a change in the level of a current passing through an electrical component or a change in a voltage applied across an electrical component. The photodetector 270 can also comprise a spectrometer (array detector with a wavelength-dispersive element) to provide data over a wide wavelength range, such as ultraviolet to visible, from about 170 nm to 800 nm. The reflected optical signal 206 undergoes constructive and/or destructive interference which increases or decreases the intensity of the optical beam, and the photodetector 270 provides an electrical output signal in relation to the measured intensity of the reflected optical signal 206. The electrical output signal is plotted as a function of time to provide a spectrum having numerous waveform patterns corresponding to the varying intensity of the reflected optical signal 206.

A computer program on the computer system 272 analyzes the shape of the measured waveform pattern of the reflected optical signal 206 to determine the endpoint of the cleaning process. The computer system 272 may be in communication with the controller 150 so as to control the cleaning process performed in the processing chamber 100. The waveform generally has a sinusoidal-like oscillating shape, with the trough of each wavelength occurring when the depth of the etched feature causes the return signal to be 180 degrees out of phase with the return signal reflected by the overlaying layer. The endpoint may be determined by calculating the cleaning/removal rate using the measured waveform, phase information of the measured waveform and/or comparison of the measured waveform to a reference waveform. As such, the period of the interference signal may be used to calculate the thickness loss of a film layer detected from the surface of the shadow frame. The program may also operate on the measured waveform to detect a characteristic waveform, such as, an inflection point indicative of a phase difference between light reflected from different layers. The operations can be simple mathematic operations, such as evaluating a moving derivative to detect an inflection point.

In one example, the shadow frame 133 may have a protrusion 205 projecting from a base 135 of the shadow frame 133. The protrusion 205 may have an upper surface 238 formed between two sidewall surfaces 239 projecting from the upper surface 240 of the base 135. Although the protrusion 205 depicted in FIG. 2A is in form of a rectangular shape, the protrusion 205 formed in the shadow frame 133 may be in any form or has other configurations. In one example, the protrusion 205 extending from the shadow frame 133 may assist the incident optical beam 204 emitted from the optical monitoring system 160 to be aimed thereon with an accurate location control. During the deposition process, the dielectric materials (such as a silicon oxide, silicon nitride, silicon oxynitride and silicon containing material) often forms on the substrate as well as on the surface 137 of the shadow frame 133. Thus, during the cleaning process, the dielectric layer accumulated on the surface 137 of the shadow frame 133 is removed or cleaned at a cleaning/removal rate similar or equal to the cleaning or removal rate to other contaminants accumulated on the chamber components disposed in the processing chamber. Thus, by aiming the incident optical beam 204 to a structure (e.g., the protrusion 205) projected above the upper surface 240 of the base 135 of the shadow frame 133, a good control, repeatability, and stability of the spot light may be obtained, thus providing accurate monitoring of the state of the shadow frame 133 disposed on the substrate support assembly 130.

In another example, a different example of a shadow frame 260 having a projecting structure 267 that projects outward from a top surface 262 of a base 261 from the shadow frame 260 is depicted in FIG. 2B. The projecting structure 267 may have an inclined surface 265 disposed an angle 299 relative to the top surface 262 of the base 261 of the shadow frame 260. The base 216 includes sidewalls 263 formed between the top surface 262 and the bottom surface 264. In one example, the angle 299 is greater than 90 degrees, such as between about 100 degrees and about 160 degrees. The inclined surface 265 provides a planar surface to where the incident optical beam 204 may be emitted at normal incidence to the surface 265, and the reflected optical signal 206 may be reflected in the reverse direction to the incident optical beam 204, such that the reflected optical signal 206 may be collected by the same optical monitoring system 160. As discussed above, the dielectric layer generated during the deposition process performed in the processing chambers 100 often is deposited on the substrate 102 as well as on the inclined surface 265 of the shadow frame 260. By utilizing the inclined surface 265 of the projecting structure 267 formed on the shadow frame 260, a more precise location control of the incident optical beam 204 may be repeatedly and reliably spotted on the substantially same location at each detection process, thus, providing an accurate determination of the state of the shadow frame 260 disposed on the substrate support assembly 130.

In yet another embodiment, a different example of a shadow frame 250 having a concave structure 254 intruded inward from a surface 255 of a base 252 from the shadow frame 250, as depicted in FIG. 2C. The concave structure 254 may have a first inclined surface 256 intersected with a second included surface 257, defining an angle 251 therebetween. In one example, the angle 251 is more than or equal to 90 degrees, such as between about 90 degrees and about 120 degrees. The first and the second inclined surfaces 256, 257 provide planar surfaces to where the incident optical beam 204 may be emitted at normal incidence to the surface 257, and the reflected optical signal 206 may be reflected in the reverse direction to the incident optical beam 204, such that the reflected optical signal 206 may be collected by the same optical monitoring system 160. In the example depicted in FIG. 2C, the incident optical beam 204 and the reflected optical signal 206 may be emitted to or reflected from the first inclined surface 256. It is noted that the incident optical beam 204 and the reflected optical signal 206 may be directed to either the first inclined surface 256 or the second included surface 257 based on the location and adjustment of the optical monitoring system 160 as needed.

As discussed above, the dielectric layer during a deposition process performed in the processing chambers 100 often forms on the substrate 102 as well as on the first inclined surface 256 and the second included surface 257 of the shadow frame 250. By utilizing the first inclined surface 256 and/or the second included surface 257 of the concave structure 254 formed on the shadow frame 250, a more precise location control of the incident optical beam 204 may be repeatedly and reliably directed to at the substantially same location at each detection, thus, providing an accurate surface detection from the shadow frame 250 disposed on the substrate support assembly 130. In one example, the concave structure 254 may have a depth 253 between about 2 mm and about 10 mm from the top surface 255 of the base 252.

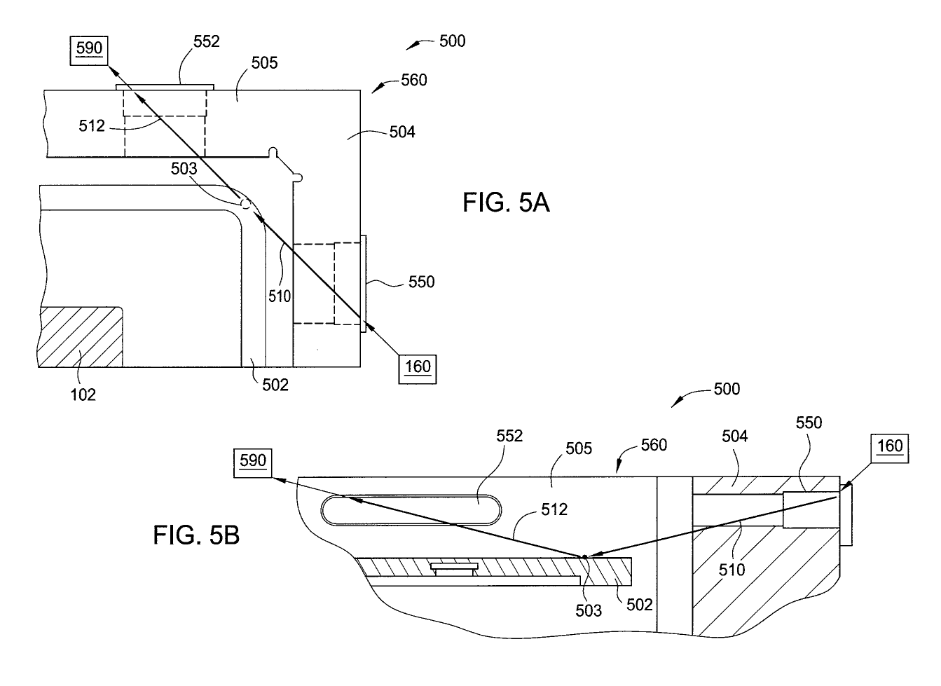

Referring first to FIGS. 5A-5B, FIGS. 5A-5B depict yet another example of a chamber configuration of a processing chamber 500 for determining a cleaning process endpoint during a cleaning process performed in the processing chamber 500. FIG. 5A depicts a top view of a portion of the processing chamber 500 having a first window 550 formed on a first sidewall 504 of a chamber body 560 and a second window 552 formed on a second sidewall 505 of the chamber body 560. The first sidewall 504 along with the second sidewall 505 defines a corner of the chamber body 560. The optical monitoring system 160 may be positioned at a location close to the first window 550 and configured to emit an incident optical beam 510, similar to the incident optical beam 204 depicted in FIGS. 2A-2C, passing through the first window 550 to a predetermined location 503 designated on a shadow frame 502 disposed in the processing chamber 500. After the incident optical beam 510 reaches to the predetermined location 503 of the shadow frame 502, a reflected optical signal 512, similar to the reflected optical signal 206 depicted in FIGS. 2A-2C, may then be generated, reflecting from the predetermined location 503 to the second window 552 disposed in the second sidewall 505. As the reflected optical signal 512 is reflected to the second window 552 without returning back to the optical monitoring system 160 through the first window 550, an additional detector 590, similar to the photodetector 270 described above, is then required to be positioned close to the second window 552 at a location that may successfully and accurately collect the reflected optical signal 512 reflected from the shadow frame 502.

FIG. 5B depicts a cross sectional view of a portion of the processing chamber 500 with the first window 550 and the second window 552 each formed in the first sidewall 504 and the second sidewall 505 of the chamber body 560 respectively. As discussed above, the incident optical beam 510 emitted from the optical monitoring system 160 reaches to the predetermined location 503 of the shadow frame 502. Once reached, the reflected optical signal 206 is generated to reflect the light beam to the additional detector 590 for analysis to determine an endpoint of the cleaning process performed in the processing chamber 500.

It is noted that the shadow frame 502 as utilized here may be any suitable shadow frame available conventionally. Alternatively, the shadow frame 502 may be one of the shadow frames 133, 260, 250 described above with referenced to FIGS. 2A-2C. Furthermore, although the example depicted in FIGS. 5A-5B depicts the incident optical beam 510 is transmitted through the first window 550 and the reflected optical signal 512 is reflected to the second window 552, it is noted that incident optical beam 510 may be transmitted through the second window 552 and the reflected optical signal 512 is reflected to the first window 550, or in any order or in any arrangement as needed.

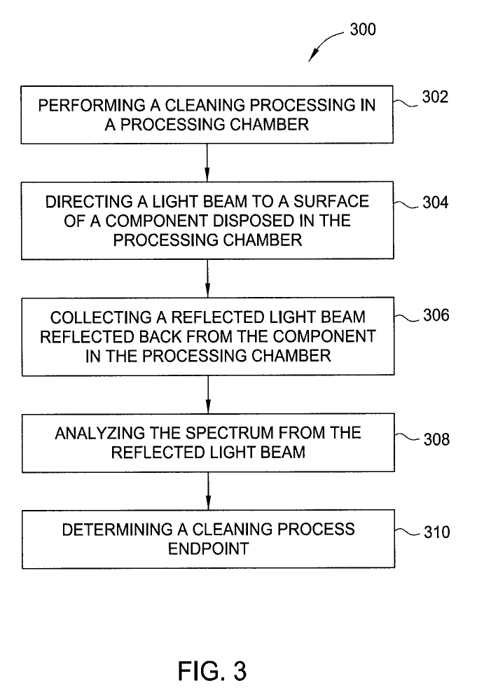

FIG. 3 is a flow diagram of one embodiment of a method 300 for detecting an endpoint for a cleaning process after or prior to a deposition process is performed in a processing chamber, such as the processing chamber 100 depicted in FIG. 1. The method 300, which may be stored in computer readable form in the memory 154 of the controller 150 (as depicted in FIG. 1), which is in signal communication with the computer system 272 in the optical monitoring system 160 (as depicted in FIG. 2A), begins at the operation 302 to perform the cleaning process and the endpoint detection process during the cleaning process. After the processing chamber 100 may be idled for a period of time or after a plasma process (including a deposition, etching, sputtering, or any plasma associated process) is performed in the plasma processing chamber 100, a cleaning process may be performed to remove chamber residuals or other contaminants. As the interior of the plasma processing chamber 100, including chamber walls, substrate support assembly 130, shadow frame 133 or other components disposed in the plasma processing chamber 100, may have film layer accumulation, by-products or contamination present thereon left over from the previous plasma processes, or flakes that have fallen of chamber inner walls while idling or plasma processing, the cleaning process may be performed to clean the interior surfaces, including the surface 137 of the shadow frame 133 disposed of the plasma processing chamber 100 after a substrate, such as the substrate 102, is removed from the processing chamber 100, or prior to providing a substrate into the plasma processing chamber 100 for subsequent processing. Furthermore, the cleaning process may be performed prior to or after each deposition process or a number of deposition processes are performed in the processing chamber and requires a cleaning process to remove chamber by-product of residuals. It is noted that the film layer accumulated on the shadow frame as described here is a dielectric material, such as silicon oxide, silicon nitride, silicon oxynitride, or silicon containing material, it is noted that the film layers to be cleaned here could be any materials left over on the chamber components to be cleaned and removed from the processing chamber 100.

It is noted that the substrate 102, being processed, to be processed or already processed, may be in a quadrilateral form from having different combination of films, structures or layers previously formed thereon to facilitate forming different device structures or different film stack on the substrate 102. The substrate 102 may be any one of glass substrate, plastic substrate, polymer substrate, metal substrate, singled substrate, roll-to-roll substrate, or other suitable transparent substrate suitable for forming a thin film transistor, LED, or OLED thereon.

The cleaning process removes contaminates and/or film accumulated from the interior of the plasma processing chamber, including the surface 137 of the shadow frame 133, thus preventing unwanted particles from falling on to the substrate disposed on the substrate pedestal during the subsequent plasma processes. While performing the cleaning process at operation 302, no substrate is present in the plasma processing chamber 100, e.g., in absence of a substrate disposed therein. The cleaning process is primarily performed to clean chamber components or inner wall/structures, including the surface 137 of the shadow frame 133, in the plasma processing chamber 100. In some cases, a dummy substrate, such as a clean silicon substrate without film stack disposed thereon, may be disposed in the processing chamber 100 to protect the surface 132 of the substrate support assembly 130 as needed.

In one example, the cleaning process is performed by supplying a cleaning gas mixture to the processing chamber 100 to clean the interior of the plasma processing chamber 100, such as the surface 137 of the shadow frame 133. The cleaning gas mixture includes at least a fluorine containing gas and an inert gas. In one embodiment, the fluorine containing gas as used in the cleaning gas mixture may be selected from a group consisting of NF₃, SF₆, HF, CF₄, and the like. The inert gas may be He or Ar and the like. In one example, the fluorine containing gas supplied in the cleaning gas mixture is NF₃ gas and the inert gas is Ar.

During the cleaning process at operation 302, several process parameters may be controlled. In one embodiment, the remote plasma source (the RPS 124 depicted in FIG. 1) may be supplied to the plasma processing chamber 100 between about 1000 Watt and about 20000 Watt, such as about 10000 Watts. The RPS power may be may be applied to the processing chamber with or without RF source and bias power. The pressure of the processing chamber may be controlled at a pressure range less than 10 Torr, such as between about 0.1 Torr and about 10 Torr, such as about 4 Torr. It is believed that the low pressure control during the cleaning process may enable the spontaneity of cleaning reaction.

The fluorine containing gas supplied in the cleaning gas mixture may be supplied into the processing chamber 100 at a flow rate between about 1 sccm and about 12000 sccm, for example about 2800 sccm. The inert gas supplied in the cleaning gas mixture may be supplied into the processing chamber at a flow rate between about 1 sccm to about 500 sccm, for example about 300 sccm.

At operation 304, while performing the cleaning process at operation 302, an incident optical beam, such as the incident optical beam 204, 510 from the optical monitoring system 160 depicted in FIGS. 2A-2C and 5A-5B, is directed to the surface 137 of the shadow frame 133 (or the surface 265, 257, 256 or location 503 of the shadow frame 260, 250, 502) simultaneously with the cleaning process performed at operation 302. The incident optical beam 204, as shown in FIG. 2A, from the optical monitoring system 160 is directed, through one of the windows in the chamber sidewall, onto one or more areas (e.g., the surface 137) of the shadow frame 133. Although in the example depicted in FIG. 2A depicts that the incident optical beam 204 is directed onto the upper surface 238 of the protrusion 205, it is noted that the incident optical beam 204 may also be directed to the surface 137, including any surfaces, such as the sidewall surfaces 239 of the protrusion 205, other portions of the shadow frame 133. It is noted that the incident optical beam 204, 510 may also be directed to any surface of the shadow frame 260, 250, 502 of FIGS. 2B-2C and 5A-5B, or other chamber components disposed in the processing chamber collectively or individually as needed for cleaning process endpoint determination when different embodiments of the shadow frames are utilized.

In one example, the incident optical beam 204 is configured to be directed onto the surface 137 of the shadow frame 133. The reflected optical signal 206, e.g., light from the incident optical beam 204 that is reflected off the surface 137 of the shadow frame 133, is detected by the photodetector 270 of the optical monitoring system 160. During the cleaning process, the intensity of the reflected optical signal 206 changes overtime. The time-varying intensity of the reflected optical signal 206 at a particular wavelength is then analyzed to determine at least one of the depth or width film layer formed on the shadow frame 133 from the previous deposition process as well as the cleaning rate so as to determine an endpoint for the cleaning process.

At operation 306, the return reflected optical signal 206 reflected from the surface 137 of the shadow frame 133 is collected (or the example of the return reflected optical signal 512 reflected from the shadow frame 502 depicted in FIGS. 5A-5B). During the cleaning process, the return reflected optical signal 206 is constantly and continuously collected from the surface 137 of the shadow frame 133. It is noted that the incident optical beam 204 may be directed to any surfaces of the shadow frame 133 without need of confinement of the incident optical beam 204 to only a certain designated region of the shadow frame 133 in order to get precise cleaning rate detection. reflected optical signal 206 reflected from surface 137 of the shadow frame 133 are constantly collected during cleaning process so as to set up a database library and develop an algorithm/model so as to precisely determine an endpoint of cleaning rate performed in the processing chamber 100.

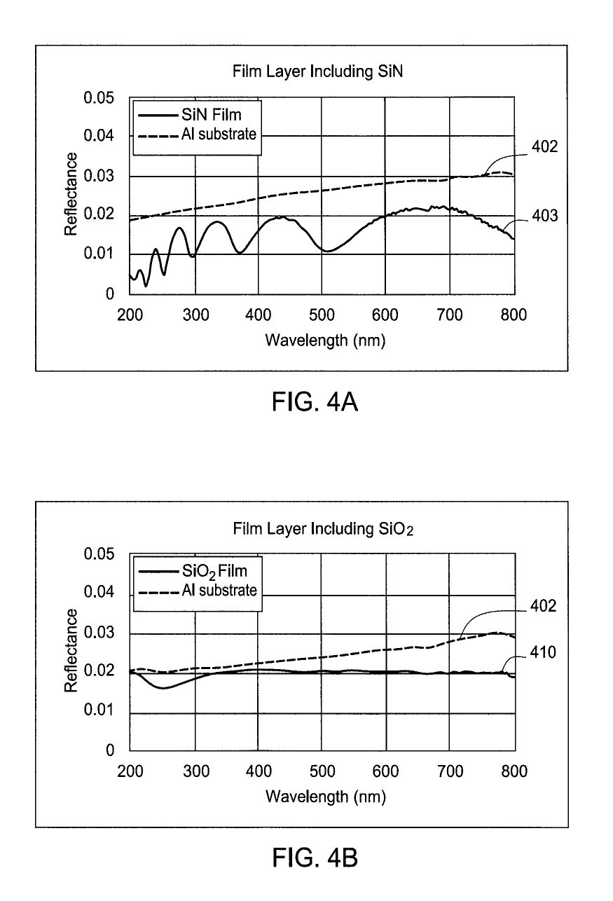

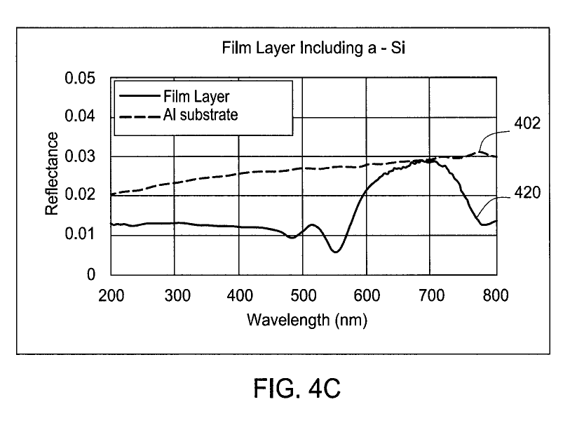

At operation 308, the return reflected optical signal 206 reflected from the surface 137 of the shadow frame 133 as collected at operation 306 is analyzed for cleaning rate determination for the cleaning process. FIGS. 4A-4C illustrate reflected optical signals as detected for cleaning determination by monitoring reflection spectra of the surface 137 of the shadow frame 133 during the cleaning process with different types of film layers disposed on the shadow frame 133. Prior to the detection of the return reflected optical signal 206 during the cleaning process, a referenced shadow frame (e.g., the shadow frame with metal (such as aluminum containing material) without film layers formed thereon) may be detected to collect a referenced reflection spectrum for a baseline setup to be compared with a reflection spectrum of a shadow frame with film layers formed thereon so as to minimize noise from the background. The referenced reflection spectrum may be stored in the database library in the computer system 272 included in the optical monitoring system 160. In one example, the referenced shadow frame as selected for background subtraction is a metal shadow frame. Examples of the materials for the shadow frame include a metal material or ceramic materials, such as bare aluminum, aluminum oxide, aluminum nitride, aluminum oxynitride, alumina coating, an aluminum body with anodized coating/surface, stainless steel or alloys thereof.

During the cleaning process, the reflected optical signal 206 is collected to provide a spectrum 403, 410, 420, as shown in FIGS. 4A-4C respectively based on different types of the film layers formed from the previous deposition processes accumulated on the shadow frame 133. The spectrum 403, 410, 420 indicates thickness variations of the film layers during the cleaning process based on different types of film layers that are detected. The reflection spectrum 403, 410, 420 is plotted as a function of wavelength, such as at a wavelength between about 200 nm and about 800 nm, to provide a waveform pattern corresponding to the varying intensity of the reflected optical signal 206. The reflection spectrum 403, 410, 420 is compared to the reference reflection spectrum 402 of an aluminum containing shadow frame without film layers residual. The reference reflection spectrum 402 is stored in the database library so as to calculate and obtain the cleaning rate and/or loss of thickness of the film layers accumulated on the shadow frame 133.

In the example of the reflection spectrum 403 depicted in FIG. 4A, the reflection spectrum 403 indicates some residual film layer of silicon nitride layer (from the previous deposition process) accumulated on the aluminum containing shadow frame 133 detected from the reflected optical signal 206 at a particular selected spectral region, such as at a wavelength between about 200 nm and about 800 nm. In contrast, when the film layer is not present (e.g., substantially cleaned or removed from) on the shadow frame 133, the reflected optical signal 206 reflected from the aluminum containing shadow frame 133 depicts a reflection spectrum similar to the reference reflection spectrum 402, as show in dotted line in FIG. 4A, indicating that the film layer accumulated on the shadow frame 133 is substantially removed and cleaned and the reflected optical signal 206 as detected is merely the aluminum containing shadow frame reflection spectrum. As shown in FIG. 4A, the reflectance intensity of the reflection spectrum 403 of silicon nitride (SiN) layer is distanced away from the reflectance intensity of the reference reflection spectrum 402 of the aluminum containing shadow frame at the wavelength between about 200 nm and about 800 nm. As such, by collecting and analyzing a change of reflectance intensity of the reflection spectrum at the wavelength between about 200 nm and about 800 nm, an endpoint of cleaning process may be determined based on the change of reflectance intensity from the measurement of the residual film layer remained on the aluminum containing shadow frame. In the example depicted in FIG. 4A, it can be reasonably determined that when a change of reflectance intensity is observed and the reflection spectrum 403 as detected and analyzed from the reflected optical signal 206 is switched to the reference reflection spectrum 402, the endpoint of the cleaning process is obtained and determined. In other words, a cleaning endpoint of the cleaning process for cleaning a silicon nitride film residual may be determined when the reflected optical signal 206 indicates that the waveform as detected has switched from a first waveform (e.g., the reflection spectrum 403) to a second waveform (e.g., the reference reflection spectrum 402).

The return reflected optical signal 206 may be detected in real-time during the cleaning process performed in the processing chamber 100. Furthermore, based on the measurement of residual film layer remained on the shadow frame 133 and the change of the reflectance intensity using the methods discussed above, the endpoint of the cleaning process parameters may be real-time adjusted and determined using in-line statistical process control (in-line SPC) for optimization of the process.

FIGS. 4B and 4C depicts yet another examples of reflection spectrum 410, 420 detected from the reflected optical signal 206 based on different types of film layers detected on the shadow frame 133 resulted from the previous deposition processes performed in the processing chamber 100. In the example depicted in FIG. 4B, the reflection spectrum 410 of silicon oxide layer (SiO₂) is detected having a different reflectance intensity from that of the reference reflection spectrum 402 of the aluminum containing shadow frame 133, particularly at the wavelength about 200 nm to 300 nm or/and about 500 nm to 800 nm. Thus, by collecting and analyzing the reflection spectrum 410 of silicon oxide layer (SiO₂) at the wavelength of between 200 nm and about 800 nm, particularly about 200 nm to 300 nm and/or about 500 nm to 800 nm, a cleaning endpoint may be determined when a change of reflectance intensity is detected and the detected spectrum has switched from the reflection spectrum 410 of silicon oxide layer (SiO₂) to the reference reflection spectrum 402 of aluminum containing shadow frame. In other words, a cleaning endpoint of the cleaning process for cleaning a silicon oxide film layer residual may be determined when the reflected optical signal 206 indicates that the waveform as detected has switched from a first waveform (e.g., the reflection spectrum 410) to a second waveform (e.g., the reference reflection spectrum 402).

Similarly, in the example depicted in FIG. 4C, the reflection spectrum 420 of a film layer including an amorphous silicon material is detected, having a different reflectance intensity from that of the reference reflection spectrum 402 of aluminum containing shadow frame 133, particularly at the wavelength at between about 200 nm and about 600 nm. Thus, by collecting and analyzing a change of reflectance intensity and the reflection spectrum 420 of the film layer including amorphous silicon at the wavelength of between 200 nm and about 800 nm, particularly between about 200 nm and about 600 nm, a cleaning endpoint may be determined when a change of reflectance intensity is detected and the detected spectrum has switched from the reflection spectrum 420 of film layer including amorphous silicon to the reference reflection spectrum 402 of the aluminum containing shadow frame. In other words, a cleaning endpoint of the cleaning process for cleaning a film layer including an amorphous silicon material may be determined when the reflected optical signal 206 indicates that the waveform as detected has switched from a first waveform (e.g., the reflection spectrum 420) to a second waveform (e.g., the reference reflection spectrum 402).

Furthermore, as the film layer including the amorphous silicon material is opaque at the wavelength at between about 200 nm and about 600 nm, by utilizing the light beam at a wavelength range beyond this range, such as between about 600 nm and 800 nm, the film layer including amorphous silicon material becomes transparent. Thus, by collecting the wavelength range at wavelength range at about 600 nm and 800 nm, when the reflected optical signal 206 as detected depicts that a change of reflectance intensity and the spectrum has altered from transparent to opaque, it indicates that the film layer including amorphous silicon has been removed/cleaned from the aluminum containing shadow frame 133 and the reflected optical signal 206 is reflected directly back from the underneath aluminum containing shadow frame 133 as aluminum containing is opaque at such wavelength range.

Furthermore, in addition to monitoring film removal end-point conditions, the optical monitoring system 160 may also be utilized to predict process kit lifetime by measuring how the aluminum target surface (e.g., the shadow frame 133 disposed in the processing chamber 100) changes over time after each cleaning process. By logging the aluminum reflectance signal at the end of each cleaning cycle and observing its long-term trend over time, the kit lifetime replacement schedule may be improved and optimized, thus reducing cost.

Thus, by monitoring a change of reflectance intensity and reflectivity of an optical beam reflected from a film layer from a shadow frame at a predetermined wavelength, a proper cleaning endpoint may be determined. The examples described herein provide an improved apparatus and method with enhanced cleaning process monitoring, control capabilities and a proper endpoint determination.

Thus, methods and apparatus for determining a cleaning endpoint for a cleaning process performed in an apparatus including a shadow frame are provided. The methods and the apparatus may advantageously provide a cleaning endpoint with enhanced accuracy by detecting a change of reflectance and obtaining a reflective optical signal reflected from a film layer disposed on a aluminum containing shadow frame, thus improving cleaning efficiency control and endpoint determination and preventing contaminants generated from incomplete cleaning process and avoid the over-cleaning, thus saving the cost of consumables and prolonging the chamber component service life and maintenance scheduling for increase production capacity.

While the foregoing is directed to embodiments of the present invention, other and further embodiments of the invention may be devised without departing from the basic scope thereof, and the scope thereof is determined by the claims that follow.

1. A method of determining a cleaning endpoint comprises:
performing a cleaning process in a plasma processing chamber;
directing an optical beam to a surface of a shadow frame during the cleaning process;
collecting a reflected optical signal reflected from the surface of the shadow frame having the optical beam incident thereon;
determining a change in intensity of the return reflected optical signal; and
determining an endpoint of the cleaning process based on the change in intensity.

2. The method of claim 1, the change of intensity is obtained by analyzing a reflectance spectrum reflected from the surface of the shadow frame.

3. The method of claim 2, wherein the change of intensity is obtained by a reflectance spectrum detected from the return reflected optical signal is changed from a first waveform to a second waveform.

4. The method of claim 1, wherein the change of intensity is determined at a wavelength between about 200 nm and about 800 nm.

5. The method of claim 1, wherein the surface of the shadow frame includes a film layer formed thereon prior to performing the cleaning process.

6. The method of claim 5, wherein the film layer includes at least a dielectric material.

7. The method of claim 6, wherein the dielectric material is at least one of a silicon nitride, silicon oxide, silicon oxynitride or a silicon containing material.

8. The method of claim 1, wherein the shadow frame include a metal material.

9. The method of claim 3, wherein the second waveform is a reference reflectance spectrum of an aluminum containing shadow frame detected at a wavelength between about 200 nm and about 800 nm.

10. The method of claim 3, wherein the first waveform is a reflectance spectrum of at least one of a silicon oxide material, silicon nitride material, or an amorphous silicon material.

11. The method of claim 1, wherein the shadow frame includes a protrusion disposed on a base, wherein the protrusion is configured to receive the optical signal directed thereto.

12. The method of claim 1, wherein the shadow frame includes a concave structure configured to receive the optical signal directed thereto.

13. The method of claim 1, wherein the shadow frame includes a projecting structure having an inclined surface configured to receive the optical beam directed thereto.

14. The method of claim 1, wherein the optical beam is directed from an optical monitoring system disposed on a sidewall of the processing chamber to the surface of the shadow frame.

15. An apparatus for performing a plasma process and a cleaning process after the plasma process, comprising:
an optical monitoring system coupled to a processing chamber, the optical monitoring system configured to direct an optical beam to a surface of a shadow frame disposed in the processing chamber and to receive a reflected optical signal reflected from the surface of the shadow frame having the optical beam incident thereon; and
a controller configured to determine a state of the shadow from in response to information derived from the optical signal.

16. The apparatus of claim 15, wherein the shadow frame comprises a protrusion configured to receive the optical beam directed thereto.

17. The apparatus of claim 15, wherein the shadow frame comprises a concave structure configured to receive the optical beam directed thereto.

18. The apparatus of claim 15, wherein the shadow frame comprises a projecting structure configured to receive the optical beam directed thereto.

19. The apparatus of claim 15, wherein the optical monitoring system is coupled to the processing chamber through a sidewall of the processing chamber.

20. A method of determining a cleaning endpoint comprises:
directing an optical signal to a surface of a shadow frame disposed in a processing chamber during a cleaning process;
collecting a return reflected optical signal reflected from the surface of the shadow frame; and
analyzing the return reflected optical signal to determine a film layer loss on the surface of the shadow frame.
